(19) United States
(12) Patent Application Publication
(10) Pub. No.: US 2026/0239533 A1
(43) Pub. Date: Aug. 13, 2026

(54) PACKAGE SUBSTRATE AND FABRICATING METHOD THEREOF

(71) Applicant: AaltoSemi Inc., Nanjing City (CN)

(72) Inventors: De-Long LIU, Nanjing City (CN); Yin-Ju CHEN, Nanjing City (CN); Sung-Kun LIN, Nanjing City (CN)

(73) Assignee: AaltoSemi Inc., Nanjing City (CN)

(21) Appl. No.: 19/535,673

(22) Filed: Feb. 10, 2026

(30) Foreign Application Priority Data
Feb. 11, 2025 (CN) 202510149982.9

(51) Int. Cl. H05K 1/11; H05K 3/18

(52) U.S. Cl. CPC H05K 1/111; H05K 3/188; H05K 2201/09036; H05K 2201/09436; H05K 2201/09509

(57) ABSTRACT

Provided is a package substrate. In a fabricating method thereof, dielectric layers are formed on a core layer having a first wiring layer and a second wiring layer, and a recess exposing the first wiring layer or the second wiring layer is formed on each of the dielectric layers. Then, a first conductive layer, a colloid, and a second conductive layer are sequentially formed within the recess. By incorporating the colloid within the recess, defects such as voids, seams, cracks, and delamination that may occur when copper is entirely electroplated into the large-area recess can be effectively avoided.

### CROSS-REFERENCE TO RELATED APPLICATION

This application claims the benefit of priority of China Patent Application No. 202510149982.9, filed on February 11, 2025, the entire contents of which are incorporated herein by reference.

### BACKGROUND

### 1. Technical Field

The present disclosure relates to semiconductor packaging technology, and more particularly, to a package substrate and a fabricating method thereof that can meet the requirements of automobile or aircraft applications.

### 2. Description of Related Art

With the rapid development of the electronics industry, electronic products have tended toward being lightweight, thin, compact, and small in form, while in functionality they are being developed in the direction of high performance, multifunctionality, and high speed.

At present, in order to meet the requirements of automobile or aircraft applications, package substrates must be designed to support specifications of high voltage and high current. This necessitates thicker copper circuit layers (or electrical contact pads) and large-area grounding terminals. However, such thicker copper circuit layers (or solder pads) and large-area grounding terminals are difficult to meet miniaturization demands. Consequently, in recent years, technologies for forming large-area grooves by means such as plasma etching or laser ablation, so as to embed circuits (or solder pads) into dielectric layers, have gradually matured.

As shown in FIG. 1, in the conventional fabricating method of a package substrate 1, a wiring layer 12 is formed on a core layer 10, and a dielectric layer 14 is subsequently formed on the wiring layer 12. After that, a large-area groove 160 is formed by means such as plasma etching or laser ablation, and a conductive material 16 is electroplated into the groove 160, which is then used as a circuit trace or a solder pad in subsequent processes.

However, in the conventional fabricating method of the package substrate 1, when electroplating copper into the large-area (large width-to-depth ratio) groove 160, defects such as seams (S), cracks (K), voids 9, and even delamination may occur. These issues result in reduced yield and poor reliability of the package substrate 1. Therefore, the conventional package substrate 1 is difficult to apply to automobiles or aircraft that require high voltage and high current specifications.

Therefore, how to overcome the various problems of the above-mentioned prior art has become an urgent issue to be solved.

### SUMMARY

The purpose of the present disclosure is to propose a package substrate and a fabricating method thereof, in order to solve at least one of the aforementioned problems.

In view of the various shortcomings of the aforementioned prior art, the present disclosure provides a package substrate, which comprises: a core layer being defined with a first side and a second side opposing the first side, the core layer having at least one conductive pillar communicating the first side and the second side; a first wiring layer and a second wiring layer respectively formed on the first side and the second side and electrically connected to the at least one conductive pillar; a plurality of dielectric layers formed on the core layer, each of the dielectric layers having at least one recess exposing the first wiring layer or the second wiring layer; a first conductive layer formed on a surface of the at least one recess and electrically connected to the first wiring layer or the second wiring layer; a colloid formed on the first conductive layer and filling the at least one recess; and a second conductive layer covering the colloid.

The present disclosure further provides a method of fabricating a package substrate, and the method comprises: providing a core layer being defined with a first side and a second side opposing the first side, the core layer having at least one conductive pillar communicating the first side and the second side, and forming a first wiring layer and a second wiring layer on the first side and the second side, respectively, the first wiring layer and the second wiring layer being electrically connected to the at least one conductive pillar; forming dielectric layers on the core layer, wherein each of the dielectric layers has at least one recess exposing the first wiring layer or the second wiring layer; forming a first conductive layer on a surface of the at least one recess, the first conductive layer being electrically connected to the first wiring layer or the second wiring layer; forming a colloid on the first conductive layer to fill the at least one recess; and forming a second conductive layer on the colloid to cover the colloid.

In the aforementioned package substrate and method, the colloid is a conductive material.

In the aforementioned package substrate and method, the colloid is a non-conductive material.

In the aforementioned package substrate and method, the second conductive layer has a protrusion at a position corresponding to the colloid, and the protrusion embeds into the first conductive layer and covers the colloid.

In the aforementioned package substrate and method, the present disclosure further comprises: forming a plurality of conductive blind vias in each of the dielectric layers, and electrically connecting the plurality of conductive blind vias to the first wiring layer or the second wiring layer.

In the aforementioned package substrate, the first conductive layer is further formed on each of the dielectric layers, the second conductive layer is further formed on the first conductive layer, and the package substrate further comprises a circuit layer formed on each of the dielectric layers by patterning the first conductive layer and the second conductive layer, the circuit layer being electrically connected to the plurality of conductive blind vias.

In the aforementioned method, the first conductive layer is further formed on each of the dielectric layers, the second conductive layer is further formed on the first conductive layer, and the method further comprises forming a circuit layer on each of the dielectric layers by patterning the first conductive layer and the second conductive layer, and electrically connecting the circuit layer to the plurality of conductive blind vias.

As can be seen from the above, in the package substrate and fabricating method thereof of the present disclosure, the configuration of the colloid enables the conductive layers (i.e., the first conductive layer and the second conductive layer) within the recess to be electroplated in two stages. This effectively prevents defects such as voids, seams, cracks, and delamination that may occur when copper is entirely electroplated into the large-area recess. Accordingly, compared with the prior art, the package substrate of the present disclosure can effectively improve yield and enhance reliability, thereby facilitating its applications to automobiles or aircraft requiring high voltage and high current specifications.

### BRIEF DESCRIPTION OF THE DRAWINGS

FIG. 1 is a schematic partial cross-sectional view showing a conventional package substrate.

FIG. 2A to FIG. 2G are schematic cross-sectional views illustrating a method of fabricating a package substrate according to the present disclosure.

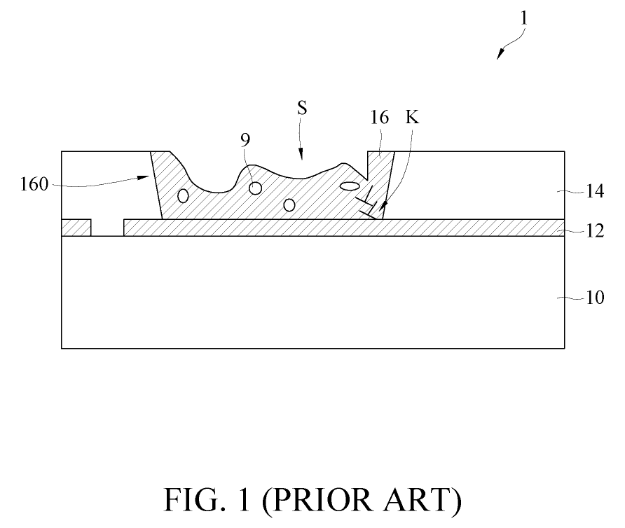

### DETAILED DESCRIPTION

The following describes the implementation of the present disclosure with examples.

Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable purposes should still be deemed as falling within the scope defined by the technical content disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical content should still be considered in the practicable scope of the present disclosure.

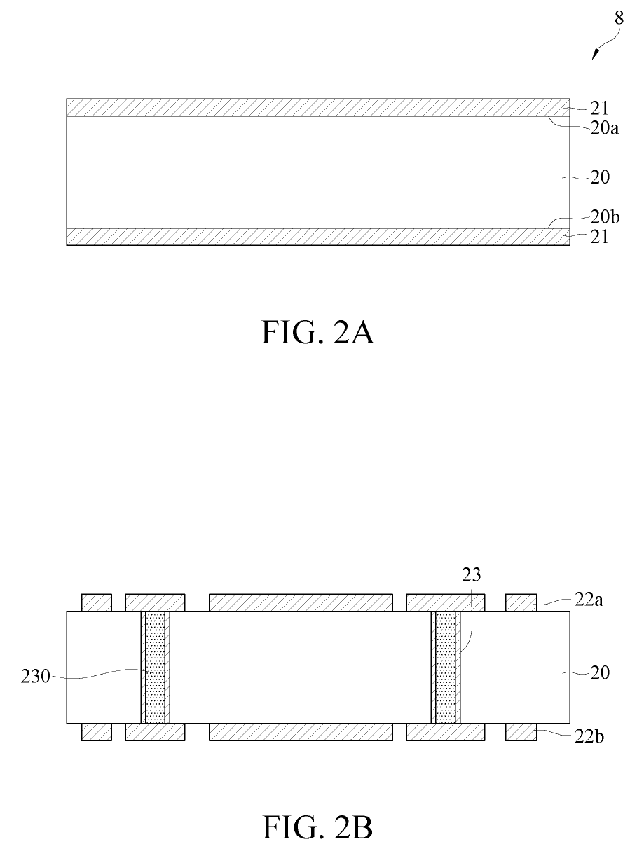

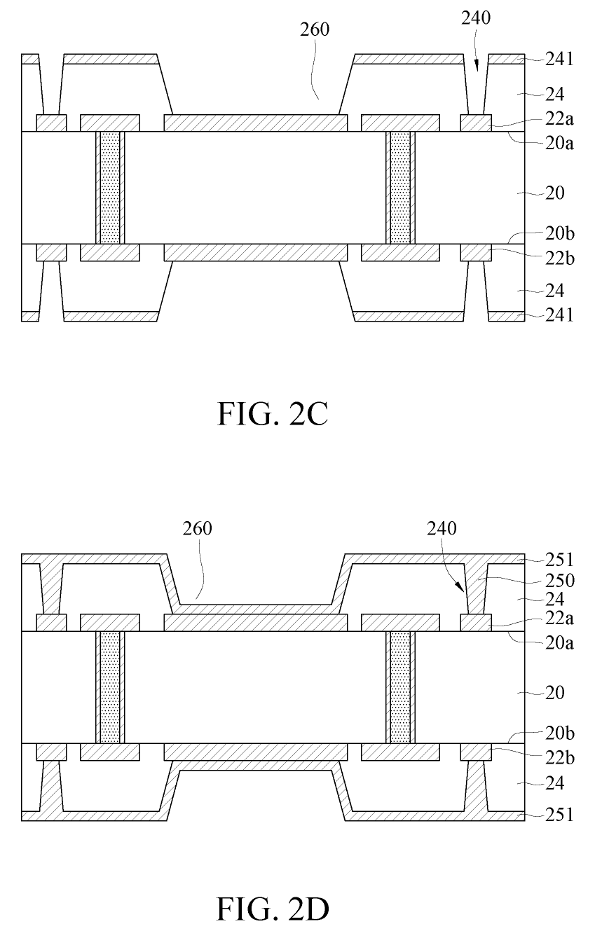

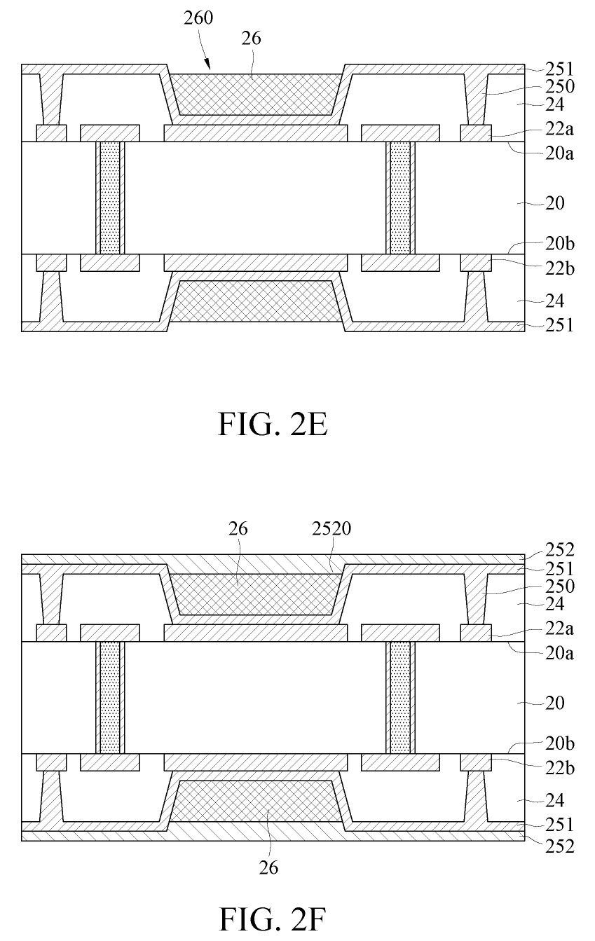

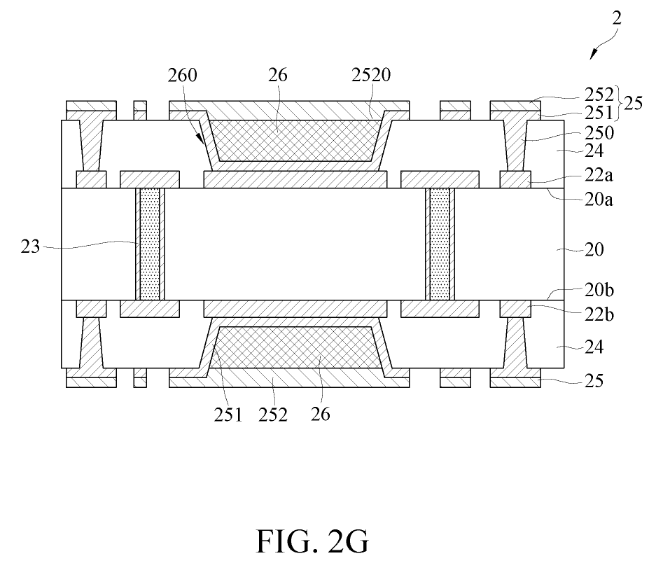

FIG. 2A to FIG. 2G are schematic cross-sectional views illustrating a method of fabricating a package substrate 2 according to the present disclosure.

As shown in FIG. 2A, a substrate 8 is provided. The substrate 8 includes a core layer 20 and metal layers 21 formed on the core layer 20.

In an embodiment, the core layer 20 is defined with a first side 20a and a second side 20b opposing the first side 20a, and the core layer 20 is an organic polymer board such as bismaleimide triazine (BT). The metal layer 21 is, for example, a copper foil. Thus, the substrate 8 is a copper foil substrate (copper-clad laminate), and the metal layer 21 can be used as a barrier layer and a seed layer.

As shown in FIG. 2B, a patterning process is performed on the metal layers 21 to form a wiring layer 22a and a wiring layer 22b on the first side 20a and the second side 20b of the core layer 20, respectively. In addition, at least one conductive pillar 23 is formed within the core layer 20 and is electrically connected to the wiring layer 22a and the wiring layer 22b.

At least one through-hole penetrating the core layer 20 may be formed by laser drilling or mechanical drilling. Then, a seed layer or a metal layer is formed on walls of the through-hole by plating. In an embodiment, the conductive pillar 23 is a hollow copper pillar, with a via-filling material 230 formed inside. For example, the via-filling material 230 may be formed by filling an ink material using injection, plugging, or coating methods. In an embodiment, the ink material primarily includes epoxy ink composites, having a viscosity of about 25 Pa∙s to about 55 Pa∙s, a glass transition temperature (Tg) of about 145 °C to about 180 °C, and/or a Young’s modulus of 3 GPa to 10 GPa.

As shown in FIG. 2C, dielectric layers 24 are formed on the first side 20a and the second side 20b of the core layer 20, respectively. Then, a plurality of openings 240 and at least one recess 260 are formed on each of the dielectric layers 24.

In an embodiment, the dielectric layer 24 is made of polybenzoxazole (PBO), polyimide (PI), prepreg (PP), or other dielectric materials, and the dielectric layer 24 is bonded to the core layer 20 by lamination. For example, when prepreg is used as the dielectric layer 24, one surface thereof has a copper layer 241, which presses the dielectric layer 24 tightly during lamination.

Moreover, the dielectric layer 24 is processed by plasma etching or other methods to form the openings 240 and the recess 260.

Furthermore, the recess 260 has a large width-to-depth ratio, which is greater than or equal to 10:20 (≥10:20), such as 10:5 or 10:10.

As shown in FIG. 2D, a first conductive layer 251 is electroplated on a surface of the recess 260 by means of the copper layer 241, and a conductive blind via 250 is formed in each of the openings 240 and is electrically connected to the wiring layer 22a, 22b.

In an embodiment, both the first conductive layer 251 and the plurality of conductive blind vias 250 are made of copper, thereby forming an integral copper surface on the surface of the dielectric layer 24. For example, a copper seed layer with a very thin thickness (about 1 μm to 3 μm) may first be formed on the copper layer 241 and on walls of the openings 240. Then, the first conductive layer 251 with a thickness of 8 μm to 10 μm may be formed, thereby substantially filling each of the openings 240 with conductive material.

As shown in FIG. 2E, a plugging process is performed to form a colloid 26 within the recess 260.

In an embodiment, the colloid 26 is a conductive material such as conductive adhesive, which fills the recess 260. For example, the colloid 26 may be a conductive adhesive containing materials such as silver, copper, or tin, with a thickness approximately equal to a thickness of the dielectric layer 24 or coplanar with the surface of the dielectric layer 24. In another embodiment, a non-conductive material such as underfill may be used as the colloid 26 according to voltage/current resistance requirements.

As shown in FIG. 2F, a second conductive layer 252 is formed on the dielectric layer 24 and covers the colloid 26.

In an embodiment, the second conductive layer 252 is formed by full-surface electroplating of copper, so as to achieve coverage of the entire board surface. In addition, at a position corresponding to the colloid 26, the second conductive layer 252 may have a protrusion 2520 that embeds into the first conductive layer 251 and covers the colloid 26.

As shown in FIG. 2G, a patterning process is performed to form a circuit layer 25 electrically connected to each of the conductive blind vias 250 on each of the dielectric layers 24 by removing portions of the first conductive layer 251 and the second conductive layer 252.

In an embodiment, the circuit layer 25 is made of copper, and may be fabricated according to redistribution layer (RDL) specifications. For example, the circuit layer 25 may be made by electroplating metal (such as copper) or by other methods.

Accordingly, in the fabricating method of the package substrate 2 of the present disclosure, the configuration of the colloid 26 enables phased electroplating operations (the first conductive layer 251 and the second conductive layer 252) within the recess 260. This effectively prevents defects such as voids, seams, cracks, and delamination that may occur when copper is entirely electroplated into the large-area (large width-to-depth ratio) recess 260. Therefore, compared with the prior art, the package substrate 2 of the present disclosure can effectively improve yield and enhance reliability.

Moreover, compared with conventional electroplating processes, the fabricating method of the present disclosure employs phased electroplating such that the second conductive layer 252 covers the colloid 26, thereby reducing or preventing seam formation.

In addition, the fabricating method of the present disclosure can effectively fabricate a package substrate 2 with a recess 260 having a large width-to-depth ratio, thereby making it suitable for automobiles or aircraft that require high voltage and high current specifications.

The present disclosure further provides a package substrate 2. The package substrate 2 comprises: a core layer 20, a wiring layer 22a, a wiring layer 22b, dielectric layers 24, at least a first conductive layer 251, at least a colloid 26, and at least a second conductive layer 252.

The core layer 20 is defined with a first side 20a and a second side 20b opposing the first side 20a, and the core layer 20 has at least one conductive pillar 23 communicating the first side 20a and the second side 20b.

The wiring layer 22a and the wiring layer 22b are respectively formed on the first side 20a and the second side 20b and are electrically connected to the conductive pillar 23.

The dielectric layers 24 are formed on the core layer 20, and each of the dielectric layers 24 has at least one recess 260 exposing the wiring layer 22a or the wiring layer 22b.

The first conductive layer 251 is formed on a surface of the recess 260 and is electrically connected to the wiring layer 22a or the wiring layer 22b.

The colloid 26 is formed on the first conductive layer 251 and fills the recess 260.

The second conductive layer 252 covers the colloid 26.

In an embodiment, the colloid 26 is a conductive material.

In an embodiment, the colloid 26 is a non-conductive material.

In an embodiment, the second conductive layer 252 may have a protrusion 2520 at a position corresponding to the colloid 26, and the protrusion 2520 embeds into the first conductive layer 251 and covers the colloid 26.

In an embodiment, the package substrate 2 further comprises a plurality of conductive blind vias 250 formed in each of the dielectric layers 24 and electrically connected to the wiring layer 22a or the wiring layer 22b.

In an embodiment, the first conductive layer 251 is further formed on each of the dielectric layers 24, and the second conductive layer 252 is further formed on the first conductive layer 251. In addition, the package substrate 2 further comprises a circuit layer 25 formed on each of the dielectric layers 24 by patterning the first conductive layer 251 and the second conductive layer 252, and the circuit layer 25 is electrically connected to the plurality of conductive blind vias 250.

In summary, in the package substrate and fabricating method thereof of the present disclosure, by utilizing the configuration of the colloid, the conductive layers within the recess are electroplated in two stages. This effectively prevents defects such as voids, seams, cracks, and delamination that may occur when copper is entirely electroplated into a large-area recess. Consequently, the package substrate of the present disclosure can effectively improve yield and enhance reliability, making it suitable for automobiles or aircraft requiring high voltage and high current specifications.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core layer defined with a first side and a second side opposing the first side, and having at least one conductive pillar communicating the first side and the second side;
a first wiring layer and a second wiring layer respectively formed on the first side and the second side and electrically connected to the at least one conductive pillar;
a plurality of dielectric layers formed on the core layer, each of the dielectric layers having at least one recess exposing the first wiring layer or the second wiring layer;
a first conductive layer formed on a surface of the at least one recess and electrically connected to the first wiring layer or the second wiring layer;
a colloid formed on the first conductive layer and filling the at least one recess; and
a second conductive layer covering the colloid.

2. The package substrate of claim 1, wherein the colloid is a conductive material.

3. The package substrate of claim 1, wherein the colloid is a non-conductive material.

4. The package substrate of claim 1, wherein the second conductive layer has a protrusion at a position corresponding to the colloid, and the protrusion embeds into the first conductive layer and covers the colloid.

5. The package substrate of claim 1, further comprising: a plurality of conductive blind vias formed in each of the dielectric layers and electrically connected to the first wiring layer or the second wiring layer.

6. The package substrate of claim 5, wherein the first conductive layer is further formed on each of the dielectric layers, and the second conductive layer is further formed on the first conductive layer.

7. The package substrate of claim 6, further comprising: a circuit layer formed on each of the dielectric layers by patterning the first conductive layer and the second conductive layer, wherein the circuit layer is electrically connected to the plurality of conductive blind vias.

8. A method of fabricating a package substrate, comprising:
providing a core layer defined with a first side and a second side opposing the first side, and having at least one conductive pillar communicating the first side and the second side, and forming a first wiring layer and a second wiring layer on the first side and the second side, respectively, wherein the first wiring layer and the second wiring layer are electrically connected to the at least one conductive pillar;
forming a plurality of dielectric layers on the core layer, wherein each of the dielectric layers has at least one recess exposing the first wiring layer or the second wiring layer;
forming a first conductive layer on a surface of the at least one recess, and electrically connecting the first conductive layer to the first wiring layer or the second wiring layer;
forming a colloid on the first conductive layer to fill the at least one recess; and
forming a second conductive layer on the colloid to cover the colloid.

9. The method of claim 8, wherein the colloid is a conductive material.

10. The method of claim 8, wherein the colloid is a non-conductive material.

11. The method of claim 8, wherein the second conductive layer has a protrusion at a position corresponding to the colloid, and the protrusion embeds into the first conductive layer and covers the colloid.

12. The method of claim 8, further comprising: forming a plurality of conductive blind vias in each of the dielectric layers, and electrically connecting the plurality of conductive blind vias to the first wiring layer or the second wiring layer.

13. The method of claim 12, wherein the first conductive layer is further formed on each of the dielectric layers, and the second conductive layer is further formed on the first conductive layer.

14. The method of claim 13, further comprising: forming a circuit layer on each of the dielectric layers by patterning the first conductive layer and the second conductive layer, and electrically connecting the circuit layer to the plurality of conductive blind vias.
